(19) United States
(12) Patent Application Publication
(10) Pub. No.: US 2009/0308433 A1
(43) Pub. Date: Dec. 17, 2009

(54) Method and apparatus for cooling of solar power cells

(75) Inventor: Franz Michael Schuette, Colorado Springs, CO (US)

Correspondence Address: WILLIAM W. HAEFLIGER, 201 S. LAKE AVE, SUITE 512, PASADENA, CA, 91101, US

(73) Assignee: Waytronx, Inc.

(21) Appl. No.: 12/214,139

(22) Filed: Jun. 17, 2008

(51) Int. Cl. H01L 31/052

(52) U.S. Cl. 136/246; 136/259; 165/104.11

(57) ABSTRACT

A solar energy apparatus, comprising in combination, a primary reflector for reflecting and focusing the sunlight and a secondary reflector to reflect the focused sunlight, a fiber optics cable located to conduct the light from the secondary reflector toward an optoelectric chip located in heat transfer relation to a heat sink.

### BACKGROUND OF THE INVENTION

This invention relates generally to powering of optoelectric chips, and more particularly to use of solar energy for that purpose.

### FIELD OF THE INVENTION

Alternative energy sources are becoming increasingly important in view of dwindling resources of fossil fuels and, more importantly, as a countermeasure against environmental pollution. Among the technologies pursued are wind farms, water turbines and solar energy farms. Water turbines may be considered the ecologically most invasive technology, whereas wind farms and solar plants are generally considered environmentally more friendly and desirable. Both technologies have their own use niches, particularly with respect to the feasibility of their installations, and based on environmental parameters such as the average number of sunny days, or the occurrence and patterns of wind, for example as caused by thermal convection.

Solar energy harvesting can be done in different ways, the most established technology in small scale use being the exposure of a radiator to sunlight for the purpose of heating up water that then can be used for general heating purposes. A more recent implementation is the use of optoelectric converters or optoelectric chips that generate electricity upon exposure to light.

A challenge associate with optoelectric chips for generating electricity is their temperature dependent efficiency derating, or short temperature derating, that is the dependency on low operating temperature. More specifically, exposure to sunlight will necessarily heat up the chip, but increasing temperatures will decrease the conversion efficiency of light to electrical energy. Accordingly, a prerequisite of operation of an efficient optoelectric chip is efficient cooling, to maintain highly efficient optoelectric conversion rates.

One method to collect solar energy is based on the use of reflectors that are focusing, and which concentrate collected light onto a small area occupied by the active die of the optoelectric chip. In that case, thermal management is difficult, because the position of the optoelectric chip in the path of sunlight demands the smallest possible chip size in order to avoid excessive shadow casting and, by extension reduction of the collection area. Small chip size, on the other hand, means a small surface area for heat dissipation into the environment. At the same time, positioning of the optoelectric chip at the focal point of the reflector requires its positioning at the highest point of the apparatus; this preempts the use of orientationally sensitive cooling technologies that rely on convection, as for example heat pipes.

The special idiosyncrasies of solar power create a unique conflict between cooling requirements and availability of cooling area with the additional problem of directional restrictions within the arrangement of components that require a novel solution. Accordingly, there is great need for apparatus and methods that obviate these difficulties and problems.

### DESCRIPTION OF RELATED ART

Most approaches for cooling optoelectric chips, as used for harvesting of solar energy, employ heat pipes or heat pipe related technology. In the latter, a partial vacuum is used to lower the boiling point of water to the desired temperature and to cause the evaporation of distilled water and the associated phase change for chilling of the heat source. Because of the directional sensitivity of this approach and the requirement for a condenser to be at higher elevation than the heat source, this type of cooling has only limited applicability in conjunction with the use with solar energy.

A different approach uses liquid cooling, however, the location of the hottest spot at the highest point of the system precludes the use of convection for moving the fluid; and standard pumps are instead used to move the fluid from the heat source to a radiator where the heat is dissipated into the environment. While liquid cooling is very efficient, the pumps also require use of electrical energy that reduces the net energy production.

### SUMMARY OF THE INVENTION

The present invention utilizes fiber optics to conduct the collected light from the focus of the reflector to the optoelectric chip. The optoelectric chip is typically positioned at the back side of the primary solar reflector, and in a typical arrangement the chip is either shadowed by the reflector or else is integrated into the backside of the reflector. In either case, the optoelectric chip is typically located at a very low position relative to the rest of the reflector and collector apparatus. Verticality and orientation are crucial factors for desirable heat transfer characteristics, in that it is relatively easy to conduct heat upwards, particularly in designs using phase change such as heat pipes. Therefore, positioning the device to be cooled at the lowest or at a relatively lower point in the combination is advantageous for heat dissipation. This is important for maintaining high efficiency of the optoelectric conversion that degrades as a function of increasing temperature.

One additional beneficiary byproduct is that the optoelectric chip is not exposed to direct sunlight that could heat up the chip or its supporting structure. The light needed for optoelectric energy generation is typically conducted via fiber optics from the apex of the structure (located at the focal point of the re-focusing reflector) to the optoelectric chip.

### UTILITY OF THE INVENTION

Advantages of the current invention can be summarized as follows:
a) No direct exposure of the optoelectric chip or supporting structures to sunlight reduces thermal load of optoelectric chip and increases optoelectric efficacy
b) Large heat spreading for thermal management of the optoelectric chip is possible without shadowing the reflector
c) Very small area of the fiber optics cable causes minimal loss of solar energy because of shadowing
d) Bottom surface of reflector can be configured for optimal aerodynamics for heat dissipation through wind-tunnel effect
e) Highly efficient cooling of the optoelectric chip increases efficacy of electricity output.

### BRIEF DESCRIPTION OF THE DRAWINGS

FIG. 1 is a schematic drawing of the solar energy apparatus consisting of the primary parabolic reflector 1, a secondary reflector 2, a fiber optics conductor 3, the optoelectric chip 4, a cooler 6 with a septum 5 to separate an upper centrifugal channel system from a lower centripetal return flow channel system;

FIG. 1a shows details of the FIG. 1 area containing the optoelectric chip;

FIGS. 2 and 3 show fiber optics and sun tracking apparatus.

### DETAILED DESCRIPTION OF THE INVENTION

The apparatus of present invention combines fiber optics with a cooling device for optoelectric chips. In the preferred embodiment, the light is focused by one reflector onto a secondary reflector 2 that further focuses the light onto the end 3a of a fiber optics system or conductor 3. The fiber optics then route the light away from the highest point in the system to a lower point, preferably in the shadow of and is alignment with the second reflector 2. See protective tubular walls 50 and 51 defining fluid coolant channels 8 and 10. This type of placement ensures that there is no additional exposure of the photovoltaic chip 4 or its assembly to direct sunlight, and thereby avoids additional heating up of the device. As a result, the optoelectric chip is located at the coolest portion of the entire solar energy apparatus. In addition, the location underneath the reflector 1 allows provision of a large auxiliary cooling apparatus 5 and 6 without incurring the problem of casting shadows on any light-collecting structure.

With respect to the actual arrangement of the fiber optics, several different embodiments are possible. One possibility entails having the fiber optics receiving light directly from the reflector and then bending down to the lower part of the apparatus in a goose-neck fashion to transmit the light towards the optoelectric chip. In this particular embodiment, the fiber optics must be relatively long in order to accommodate the curved route, which results in higher materials cost and lower efficiency with respect to light transmission.

A greatly simplified and preferred configuration employs the fiber optics running in axial direction upward from the center of the parabolic first reflector 1. In this case, the distal face of the fiber optics points upward, that is away from the first reflector 1. In order to receive light, therefore, an additional mirror is provided at 2 to reflect the light back onto the end face 3a of the fiber optics conductor 3. The fiber optics further pass through the center of the first reflector 1 to its back side where the optoelectric chip 4 is typically located. The advantage of this particular arrangement is that the fiber optics are routed the shortest way in a straight line from their light receiving face to the emitting end. Moreover, since the fiber optics extend in axial direction away from the center of the first reflector, they are oriented in parallel with the incoming solar rays and, consequently do not cast any further shadows that would reduce the efficiency of the solar energy-collecting apparatus.

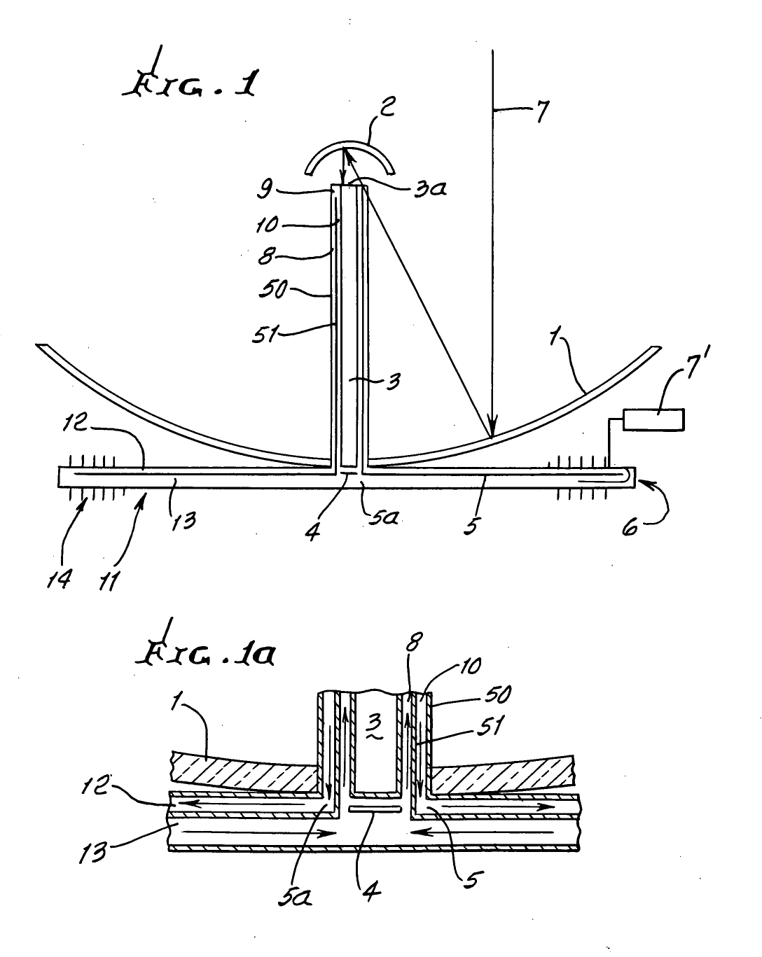

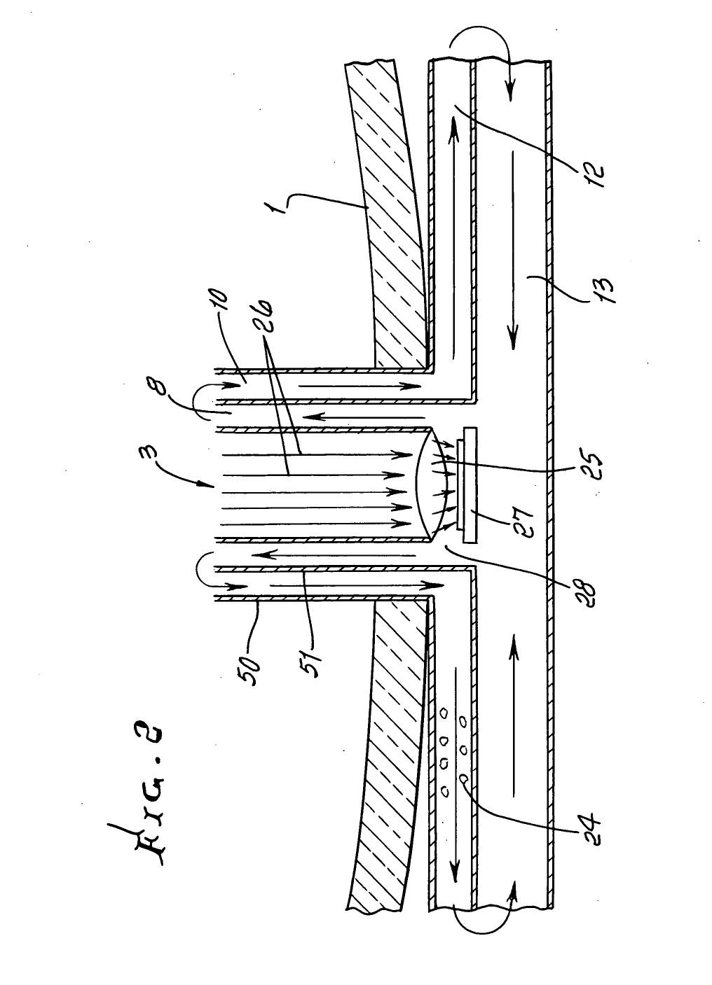

On average, the highest amount of solar energy is collected when the sun it at its apex. The reflector is always tracking the sun using a rotatable platform for the azimuth and a tilting mechanism for adjusting the altitude. Therefore, during peak exposure times, the fiber optics will extend upwards in a substantially vertical direction, which is advantageous for creating buoyancy as a function of thermal gradients and using the buoyancy for fluid movement. This greatly facilitates the implementation of liquid cooling. In this case, the optoelectric chip 4, which absorbs the sunlight conducted by the fiber optics and consequently generates a substantial amount of heat, is positioned at the bottom of the assembly and gives off or transfers heat to the coolant used as at 5a. The coolant absorbs the heat from the optoelectric chip, thereby warming up and, as a consequence develops buoyancy. A channel or path 8 seen in FIG. 1a extends along the fiber optics cable in parallel direction and serves as chimney in which the coolant rises. At the top 9 of the column, the channel 8 loops and turns into a return channel 10 that feeds into the radiator 11. The radiator itself is divided into an upper layer 12 in which fluid travels centrifugally or outwardly, and a lower layer 13 which works as a centripetal return path for the fluid to the optoelectric chip 4. As a consequence, as soon as the optoelectric chip receives light and gives off heat as by-product, the same heat will result in a buoyancy pump action to move fluid along such paths. It is possible to further use the coolant as immersion fluid to enhance the light transmission from the fiber optics to the optoelectric chip.

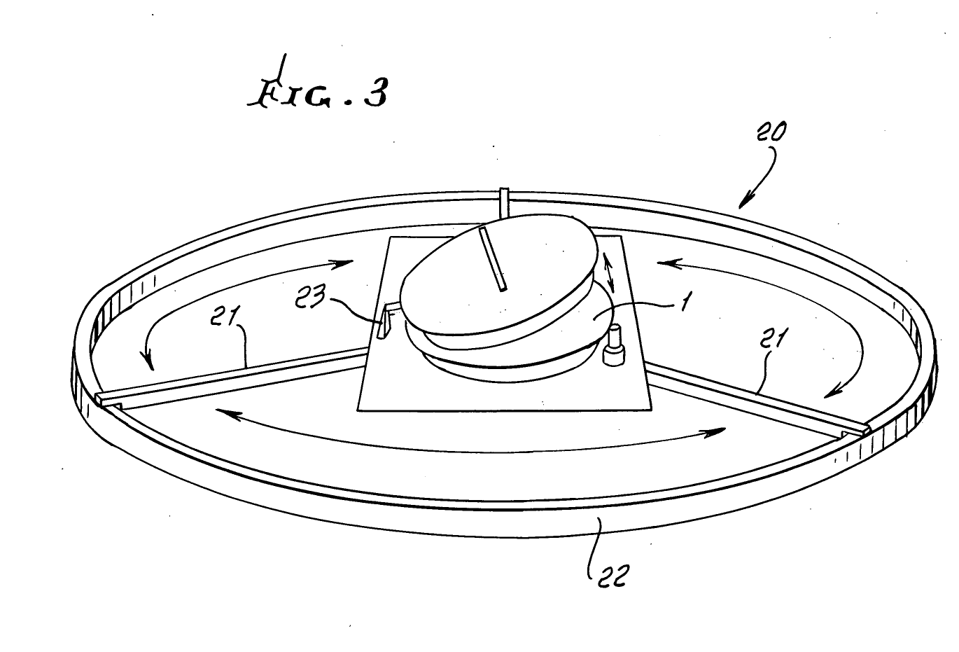

The backside of the radiator can be equipped with fins 14 for increased surface to dissipate the heat into the environment. The inside of the radiator preferably contains a network of micro-channels that can be formed for example by embedding a mesh 25 (see FIG. 2) that is bonded to the walls in a thermally conductive fashion and where the interstices between the strands form the fluid channel system.

FIG. 3 is a schematic view showing a tracking mechanism 20 in which a rotatable tripod 21 is mounted on a circular rail 22 for tracking of the azimuth of the sun position, with the reflectors carried as shown; and the reflector assembly is hinged at 23 to allow tilting for tracking of the sun's altitude.

FIG. 2 is a schematic view showing of the light path from the fiber optics to the optoelectric chip, in which a lens 25 is used at the lower end of 3 for focusing the light from the parallel optical fibers 26 onto the optoelectric chips array at 27. The coolant at 28 also serves as optical immersion fluid. Arrows show coolant fluid paths.

Reflector 1 in FIG. 2 may be curved, or flat.

I claim:

1. A solar energy apparatus, comprising in combination:
a) a primary reflector for reflecting and focusing the sunlight and a secondary reflector to reflect the focused sunlight,
b) a fiber optics cable located to conduct the light from the secondary reflector toward an optoelectric chip located in heat transfer relation to a heat sink.

2. The combination of claim 1 wherein the chip is located in alignment with the fiber optics cable extending toward the rear of the primary reflector.

3. The combination of claim 1 wherein the fiber optics cable extends in generally axial direction along the center axis of the primary reflector.

4. The combination of claim 1 wherein the heat sink includes a fluid channel system that extends proximate the fiber optics cable and receives fluid from a cooling system using said fluid as a chip coolant.

5. The combination of claim 4 wherein the heat sink includes a cooling radiator positioned at the back sides of the primary reflector.

6. The combination of claim 4 wherein the fluid channel system is configured to use convection for movement of the fluid from the heat generating chip to a heat radiator.

7. The method of cooling an optoelectric chip used in a solar energy apparatus, that includes the steps:
a) providing a primary reflector for reflecting and focusing the sunlight and a secondary reflector to reflect the focused sunlight,
b) and providing a fiber optics cable to conduct the sun light from the secondary reflector toward an optoelectric chip located in heat transfer relative to a heat sink.

8. The method of claim 7 wherein the fiber optics cable is extended in generally axial direction along the center axis of the primary reflector.

9. The method of claim 7 wherein the heat sink is provided to include a fluid channel system that extends along the fiber optics cable and wherein the fluid channel system is configured to receive fluid from a cooling system using said fluid as coolant.

10. The method of claim 9 wherein a cooling radiator is provided at the back of the primary reflector, and is configured as part of the heat sink.

11. The method of claim 9 wherein the fluid channel system is configured to use convection for movement of the fluid from the heat generating chip source to the radiator.

12. The method of cooling an optoelectric chip used in a solar energy apparatus, that includes using reflectors for reflecting and focusing the sunlight onto the face of a fiber optics cable that conducts the light to an optoelectric chip located behind a reflector associated with a heat sink.

13. The method of claim 12 including providing and employing a sun azimuth tracking apparatus carrying said reflector, cable and chip.

14. The method of claim 12 including providing a light focusing lens in the light path between the cable and chip, there being fluid coolant in said path.

15. Solar energy conversion apparatus comprising, in combination
a) an optoelectric chip,
b) a fiber optic configured to transmit solar energy toward said chip.
c) and solar energy reflector means configured to direct solar energy into said fiber optic,
d) said reflector means encompassing at least part of said fiber optic.

16. The combination of claim 15 including means forming fluid coolant paths that extend from said chip along said fiber optic, then to a heat transfer structure, and then back to the chip.

17. The combination of claim 15 wherein said reflector means include first and second solar reflectors, the first reflector having a mid portion associated with the chip, and the second reflector associated with an end of the fiber optic remote from the chip.

18. The combination of claim 17 wherein the second reflector is configured to receive solar energy from the first reflector, and to direct said energy into said end of the fiber optic.

19. The combination of claim 15 including sun azimuth tracking apparatus carrying said reflector means, said fiber optic, and said chip.

20. The combination of claim 15 including a light focusing lens between the cable and chip, and there being fluid coolant located between the cable and chip.

21. Solar energy conversion apparatus comprising, in combination
c) an optoelectric chip,
d) a fiber optic configured to transmit solar energy toward said chip.
c) and solar energy reflector means configured to direct solar energy into said fiber optic,
d) said reflector means encompassing at least part of said fiber optic,
e) there being means forming fluid coolant paths that extend from said chip along said fiber optic, then to a heat transfer structure, having centrifugal and centripetal flow paths, at least one of which contains a mesh, and then back to the chip,
f) said reflector means including first and second reflectors, the first reflector having a mid portion associated with the chip, and the second reflector associated with an ed of the fiber optic remote from the chip, the fiber optic also passing through said mix-portion,
g) said second reflector configured to receive solar energy from the first reflector, and to direct said energy into said end of the fiber optic,
h) and including sun azimuth tracking apparatus carrying said reflector means, said fiber optic, and said chip,
i) and there being a light focusing lens between the cable and chip, and there also being fluid coolant located between the cable and chip.

22. The method of cooling an optoelectric chip used in a solar energy apparatus, that includes the steps:
a) providing a primary reflector for reflecting and focusing the sunlight and a secondary reflector to reflect the focused sunlight,
b) and providing a fiber optics cable to conduct the sun light from the secondary reflector toward an optoelectric chip located in heat transfer relation to a heat sink,
c) said fiber optics cable extended in generally axial direction along the center axis of the primary reflector, and through the center of the primary reflector,
d) and wherein the heat sink is provided to include a fluid channel system that extends along the fiber optics cable and wherein the fluid channel system is configured to receive fluid from a cooling system using said fluid as coolant,
e) a cooling radiator being provided at the back side of the primary reflector, and configured as part of the head sink,
f) and wherein the fluid channel system is configured to use convection for movement of the fluid from the heat generating chip source to the radiator.
